(19) United States
(12) Patent Application Publication
(10) Pub. No.: US 2012/0032217 A1
(43) Pub. Date: Feb. 9, 2012

(54) WHITE LED DEVICE AND MANUFACTURING METHOD THEREOF

(75) Inventor: Jui-Kang Yen, Hsinchu (TW)

(73) Assignee: Semileds Optoelectronics Co., Ltd., a Taiwanese Corporation, Chu-Nan (TW)

(21) Appl. No.: 13/118,337

(22) Filed: May 27, 2011

(30) Foreign Application Priority Data
Aug. 6, 2010 (TW) 099126317

(51) Int. Cl. H01L 33/50

(52) U.S. Cl. 257/98; 438/29; 257/E33.067; 257/E33.073

(57) ABSTRACT

The invention provides a white light emitting diode device, which includes: a conductive substrate; a multilayered light emitting semiconductor epitaxial structure formed on the conductive substrate; a contact provided on the multilayered light emitting semiconductor epitaxial structure; a transparent layer provided on the multilayered light emitting semiconductor epitaxial structure; a wavelength converting layer provided on the transparent layer; and an optical layer provided on the wavelength converting layer. The invention also provides a method of manufacturing the white light emitting diode device.

### CLAIM OF PRIORITY

This application claims the priority benefit of Taiwan Application Ser. No. 099126317, filed on Aug. 6, 2010. All disclosure of the Taiwan application is incorporated herein by reference.

### BACKGROUND OF THE INVENTION

A. Field of the Invention

The present invention is related to a white light emitting diode (LED) device and a manufacturing method thereof.

B. Description of the Prior Art

In a conventional LED device, such as the LED device disclosed in U.S. Pat. No. 5,998,925, a phosphor layer with a wavelength converting function is frequently provided to change the wavelength of a light emitted by the LED device. However, the phosphor layer usually has a thicker thickness and contacts with the LED device directly, thereby causing various adverse problems. For examples, the distribution of phosphor powder in the phosphor layer is uneven; the aging of phosphor layer is speeded up due to the heat generated by the LED device, which would significantly reduce the life of the LED device; and so on. Furthermore, in the LED device disclosed in U.S. Pat. No. 5,998,925, the color of the light emitted by the LED device was measured after the assembly or package of the entire LED device is completed. If it is found that the wavelength of the light emitted fails to meet the specification, the production cost would be significantly increased because the rework is very difficult, or even the failed products must be scrapped right away. Moreover, since the conventional method of coating a phosphor layer is generally performed by a dispensing process, the conventional phosphor layer may have a larger thickness. Therefore, there will be a yellow ring issue and phosphor powder may sink down in the phosphor layer due to gravity, thereby reducing the color uniformity of LED device. The brightness of LED will drop by reducing the thickness of phosphor layer. The heat generated by the LED device also ages the phosphor layer and decrease its life. Accordingly, it is strongly required that a LED device and manufacturing method thereof can overcome the foregoing problems.

### SUMMARY OF THE INVENTION

According to one aspect of the invention, a method of manufacturing a white light emitting diode is provided, the method includes the following steps: providing an optical layer; providing a wavelength converting layer on the optical layer to form a first stack structure including the optical layer and the wavelength converting layer; providing a conductive substrate; forming a multilayered light emitting semiconductor epitaxial structure on the conductive substrate to form a second stack structure including the conductive substrate and the multilayered light emitting semiconductor epitaxial structure; cutting the first stack structure into a size matching the second stack structure; and bonding the wavelength converting layer of the first stack structure to the multilayered light emitting semiconductor epitaxial structure of the second stack structure, while providing a transparent layer between the wavelength converting layer and the multilayered light emitting semiconductor epitaxial structure.

According to another aspect of the invention, a white light emitting diode device is provided, the device includes: a conductive substrate; a multilayered light emitting semiconductor epitaxial structure formed on the conductive substrate; a contact provided on the multilayered light emitting semiconductor epitaxial structure; a transparent layer provided on the multilayered light emitting semiconductor epitaxial structure; a wavelength converting layer provided on the transparent layer; and an optical layer provided on the wavelength converting layer.

Other aspects and advantages of the invention will become more apparent from the following detailed description, taken in conjunction with the accompanying drawings illustrating exemplifications of the principles of the invention.

### BRIEF DESCRIPTION OF THE DRAWINGS

In the accompanying drawings of the invention, like reference numerals refer to similar elements, in which:

FIG. 1 is a schematic cross sectional view of a white light emitting diode device according to an embodiment of the invention;

FIGS. 2a-2g illustrate exemplary steps of manufacturing the white light emitting diode device in FIG. 1;

FIG. 3 shows a schematic cross sectional view of a white light emitting diode device according to another embodiment of the invention;

FIGS. 4a-4e illustrate exemplary steps of manufacturing the white light emitting diode device in FIG. 3;

FIG. 5 is a schematic cross sectional view of a white light emitting diode device according to yet another embodiment of the invention; and

FIGS. 6a-6g illustrate exemplary steps of manufacturing the white light emitting diode device in FIG. 5.

### DETAILED DESCRIPTION OF THE PREFERRED EMBODIMENTS

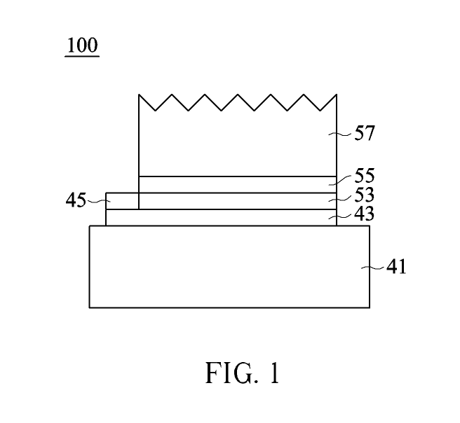

FIG. 1 is a schematic cross sectional view of a white light emitting diode (LED) device 100 according to an embodiment of the invention. As shown in FIG. 1, white light emitting diode device 100 includes: a conductive substrate 41; a multilayered light emitting semiconductor epitaxial structure 43 formed on the conductive substrate 41; a contact (electrode) 45 provided on the multilayered light emitting semiconductor epitaxial structure 43; a transparent layer 53 provided on the multilayered light emitting semiconductor epitaxial structure 43; a wavelength converting layer 55 provided on the transparent layer 53; and an optical layer 57 provided on the wavelength converting layer 55. The conductive substrate 41 may be a metal or an alloy, such as copper or copper alloy, or may be silicon (Si). The multilayered light emitting semiconductor epitaxial structure 43 may include a p-type semiconductor layer, an active layer formed on the p-type semiconductor layer, and an n-type semiconductor layer formed on the active layer. In one example of the invention, the p-type semiconductor layer is formed on and adjacent to the conductive substrate 41; while in another example, the n-type semiconductor layer is formed on and adjacent to the conductive substrate 41. The transparent layer 53 may be made of a polymer, such as a silicone resin, an epoxy resin, or other transparent resins. The refractive index of the transparent layer 53 is more than or equal to 1.40, and preferably 1.50 or above. Furthermore, the transparent layer 53 is provided between the multilayered light emitting semiconductor epitaxial structure 43 and the wavelength converting layer 55. In one embodiment of the invention, the wavelength converting layer 55 may consist of a plurality of wavelength converting sublayers. For example, it may include two wavelength converting sublayers, i.e. a first wavelength converting sublayer and a second wavelength converting sublayer provided on the first wavelength converting sublayer (not shown), in which each of the first wavelength converting sublayer and the second wavelength converting sublayer includes phosphors and organic resins. Furthermore, the first wavelength converting sublayer and the second wavelength converting sublayer may have similar or different phosphors and organic resins. The thickness of the wavelength converting layer 55 is less than about 200 μm, preferably less than about 50 μm. However, in other examples, the wavelength converting layer 55 may also be a single wavelength converting layer. The optical layer 57 may have a roughened surface to increase the light extraction efficiency of the white light emitting diode device 100. The optical layer 57 may be made of a polymer, such as a silicone resin, an epoxy resin, or other transparent resins. The thickness of the optical layer 57 is between about 150 μm and about 400 μm, preferably about 200 μm. In various embodiments of the invention, the optical layer may be in the form of a dome, a convex, a concave, a flat, or a Fresnel lens, and the surface of the optical layer may be roughened optionally.

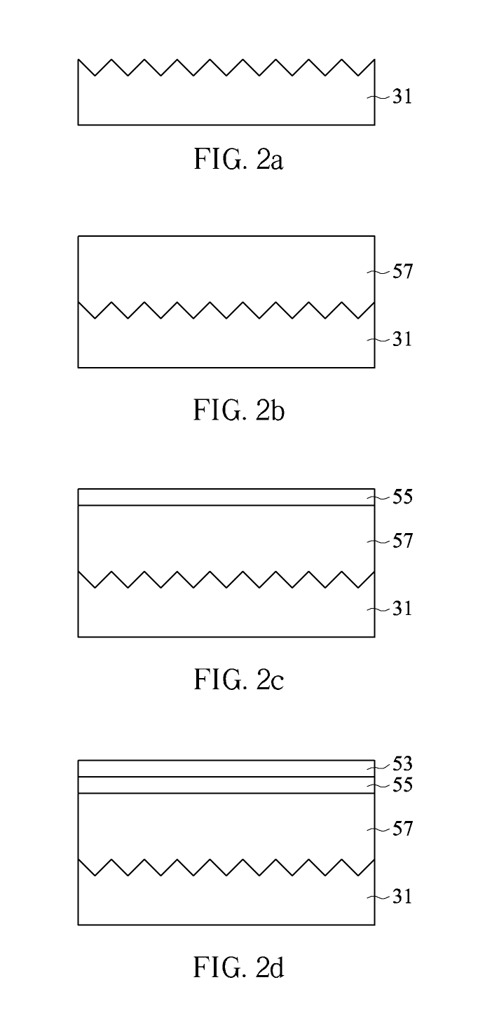

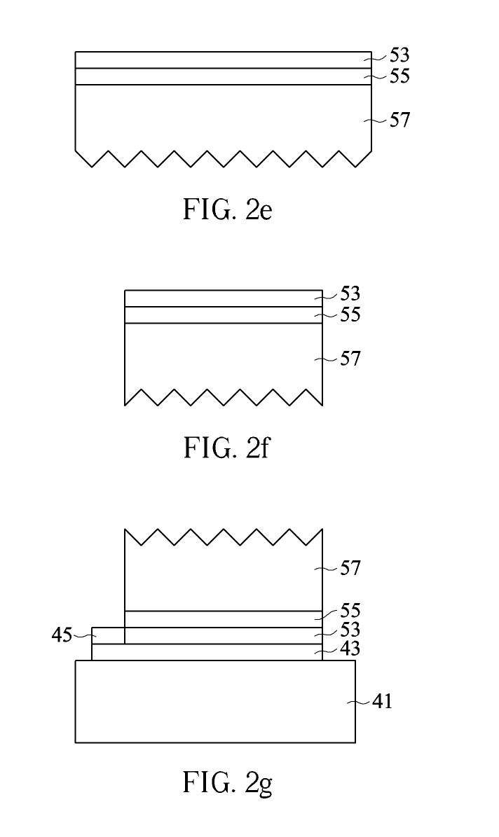

FIGS. 2a-2g illustrate exemplary steps of manufacturing the white light emitting diode device 100 in FIG. 1. As shown in FIGS. 2a-2g, the optical layer 57 is provided on a rough surface mold 31 by injection molding, compress molding, or casting and so on. The roughing of the mold surface is achieved by a sand blasting or etching process, so that the surface of the optical layer 57 may have a predetermined roughness. In another embodiment of the invention, the mold 31 may be provided without the surface roughening treatment. Instead of the treatment, the surface of the optical layer 57 is directly treated by a sand blasting or etching process. Therefore, the optical layer 57 may have a surface with a predetermined roughness. The mold 31 can be made of a material such as glass, stainless steel, or rubber.

The wavelength converting layer 55 (as a carrier) is provided on the optical layer 57 by spraying coating, spin coating, jet printing, or screen printing and so on. The transparent layer 53 is provided on the wavelength converting layer 55 by spraying coating, spin coating, jet printing, or screen printing and so on. The first stack structure including the transparent layer 53, the wavelength converting layer 55 and the optical layer 57 is given by removing the mold 31.

In another embodiment of the invention, a transparent polymer film that does or does not undergo a surface roughening treatment can be provided as the optical layer 57.

The multilayered light emitting semiconductor epitaxial structure 43 is formed on the conductive substrate 41, so as to form a second stack structure including the conductive substrate 41 and the multilayered light emitting semiconductor epitaxial structure 43. The contact (electrode) 45 is provided on the multilayered light emitting semiconductor epitaxial structure 43.

Then, the first stack structure is cut into a size fitting the second stack structure.

In the embodiment, the mold 31 is removed before the first stack structure is cut. However, in other embodiments, the mold 31 can be removed after the optical layer 57 is provided but before the wavelength converting layer 55 is provided. Alternatively, the mold 31 may be removed after the wavelength converting layer 55 is provided but before the transparent layer 53 is provided.

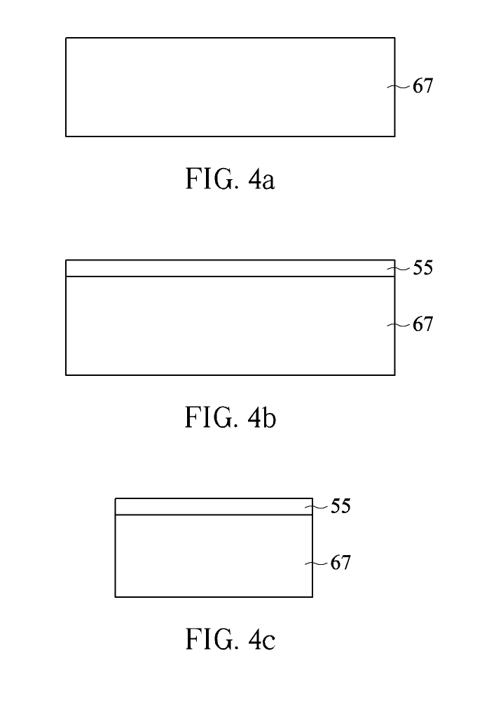

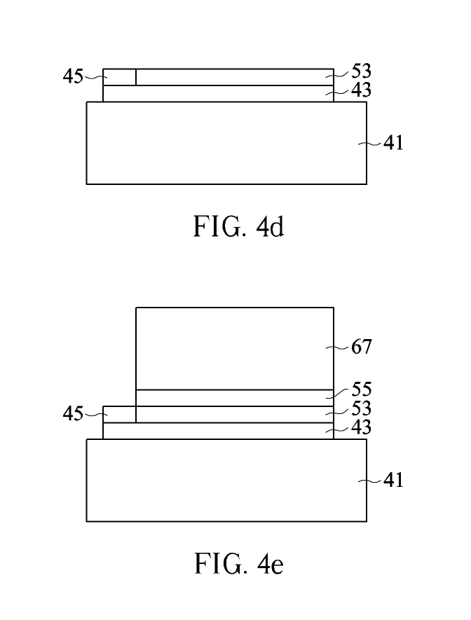

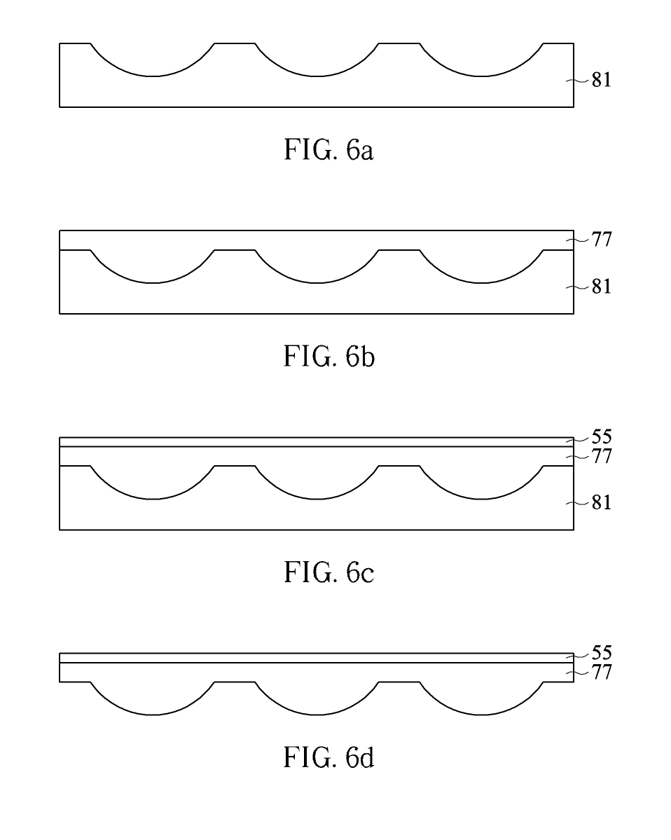

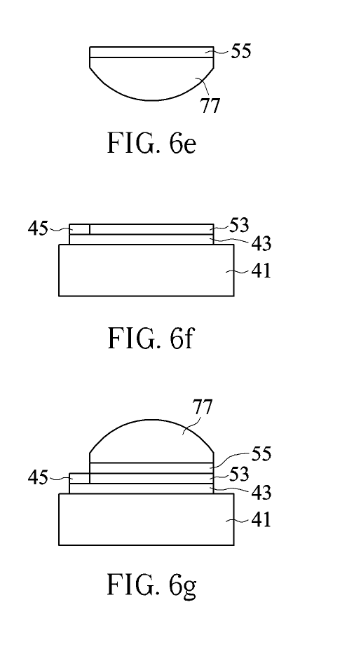

Finally, the first stack structure is bonded to the second stack structure. Specifically, the wavelength converting layer 55 of the first stack structure is bonded to the multilayered light emitting semiconductor epitaxial structure 43 of the second stack structure, and the transparent layer 53 is provided therebetween, so as to produce the white light emitting diode device 100. However, in other embodiments of the invention, the transparent layer 53 can be provided on the second stack structure rather than on the first stack structure, as shown in FIGS. 4a-4e and FIGS. 6a-6g. Alternatively, the transparent layer 53 can be provided on the first stack structure and the second stack structure, respectively, as long as the transparent layer 53 is placed between the multilayered light emitting semiconductor epitaxial structure 43 and the wavelength converting layer 55 after the bonding, i.e. the transparent layer 53 is provided between the multilayered light emitting semiconductor epitaxial structure 43 and the wavelength converting layer 55.

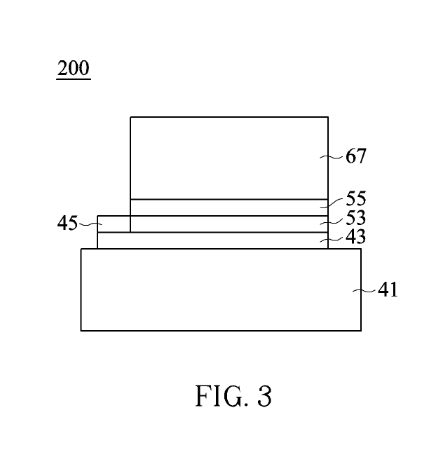

FIG. 3 shows a schematic cross sectional view of a white light emitting diode device 200 according to another embodiment of the invention. The white light emitting diode device 200 in FIG. 3 is similar to the white light emitting diode device 100 in FIG. 1, the difference therebetween is that an optical layer 67 of the white light emitting diode device 200 in FIG. 3 dose not have a roughened surface, and it is a transparent window to increase the light extraction efficiency. FIGS. 4a-4e illustrate the steps of manufacturing the white light emitting diode device 200 in FIG. 3. FIGS. 4a-4e illustrate the embodiment without applying the mold. In another embodiment, the mold can be employed to provide the optical layer 67, as shown in FIG. 2.

As shown in FIGS. 4a-4e, the optical layer 67 is provided. Then the wavelength converting layer 55 is provided on the optical layer 67 to form a first stack structure including the optical layer 67 and the wavelength converting layer 55. The multilayered light emitting semiconductor epitaxial structure 43 and the transparent layer 53 are formed sequentially on the conductive substrate 41, such that a second stack structure having the transparent layer 53 thereon is formed. The second stack structure includes the conductive substrate 41 and the multilayered light emitting semiconductor epitaxial structure 43. The contact (electrode) 45 is provided on the multilayered light emitting semiconductor epitaxial structure 43.

Then, the first stack structure is cut into a size fitting the second stack structure.

Finally, the first stack structure is bonded to the second stack structure, so as to produce the white light emitting diode device 200.

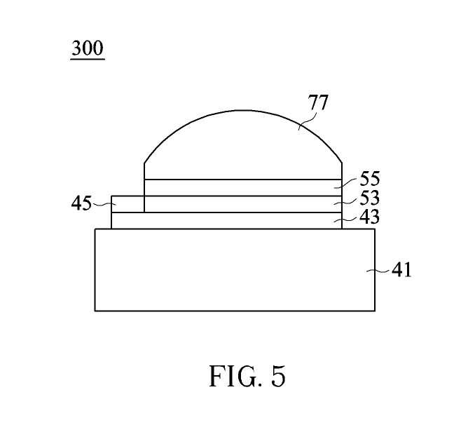

FIG. 5 shows a schematic cross sectional view of a white light emitting diode device 300 according to another embodiment of the invention. The white light emitting diode device 300 in FIG. 5 is similar to the white light emitting diode device 100 in FIG. 1, the difference therebetween is that an optical layer 77 of the white light emitting diode device 300 in FIG. 5 is a dome lens, such that the light pattern of the white light emitting diode device 300 can be changed. FIGS. 6a-6g illustrate the steps of manufacturing the white light emitting diode device 300 in FIG. 5. As shown in FIGS. 6a-6g, the optical layer 77 is provided on a mold 81, which does or does not undergo a surface roughening treatment, and can be made of a material such as glass, stainless steel or rubber. Next, the wavelength converting layer 55 is provided on the optical layer 77. After that, the mold 81 is removed, so as to give a first stack structure including the optical layer 77 and the wavelength converting layer 55.

The multilayered light emitting semiconductor epitaxial structure 43 and the transparent layer 53 are formed sequentially on the conductive substrate 41 The second stack structure includes the conductive substrate 41, the multilayered light emitting semiconductor epitaxial structure 43, and the transparent layer 53. The contact (electrode) 45 is provided on the multilayered light emitting semiconductor epitaxial structure 43.

Then, the first stack structure is cut into a size fitting the second stack structure.

Finally, the first stack structure is bonded to the second stack structure to produce the white light emitting diode device 300. Specifically, the wavelength converting layer 55 of the first stack structure is bonded to the multilayered light emitting semiconductor epitaxial structure 43 of the second stack structure, and the transparent layer 53 is provided between the wavelength converting layer 55 and the multilayered light emitting semiconductor epitaxial structure 43.

As compared with the prior art, the present invention has following advantages: having the better color uniformity without the yellow ring issue; the wavelength converting layer not directly contacting with the multilayered light emitting semiconductor epitaxial structure (since the transparent layer is provided therebetween), thereby increasing the life of the LED device and improving the stability; the light extraction efficiency being improved and/or the light pattern being changed via the optical layer; and so on. Moreover, the wavelength converting layer has been provided on the optical layer, the color of the wavelength converting layer can be tested before the assembly or package of the entire light emitting diode device is completed to determine whether the color falls within the specification. If not, the LED device of the invention can be easily reworked, thereby reducing the production cost significantly.

While the present invention has been described in details with reference to preferred embodiments and figures thereof, it should be apparent to a person skilled in the art that various modifications, alterations and equivalent substitutions could be made without departing from the spirit and scope of the present invention. However, such modifications, alterations and equivalent substitutions are intended to be embraced in the appended claims.

What is claimed is:

1. A method of manufacturing a white light emitting diode, comprising:
providing an optical layer;
providing a wavelength converting layer on the optical layer to form a first stack structure including the optical layer and the wavelength converting layer;
providing a conductive substrate;
forming a multilayered light emitting semiconductor epitaxial structure on the conductive substrate to form a second stack structure including the conductive substrate and the multilayered light emitting semiconductor epitaxial structure;
cutting the first stack structure into a size fitting the second stack structure; and
bonding the wavelength converting layer of the first stack structure to the multilayered light emitting semiconductor epitaxial structure of the second stack structure, while providing a transparent layer between the wavelength converting layer and the multilayered light emitting semiconductor epitaxial structure.

2. The method of claim 1, wherein the optical layer is provided by using a mold.

3. The method of claim 2, wherein the optical layer is provided on the mold by injection molding, or compress molding, or casting.

4. The method of claim 2, wherein the mold is made of glass, stainless steel, or rubber.

5. The method of claims 2, wherein the mold undergoes a surface roughening treatment.

6. The method of claim 5, wherein the surface roughening treatment includes sand blasting or etching.

7. The method of claim 1, wherein a surface of the optical layer undergoes a roughening treatment.

8. The method of claim 7, wherein the roughening treatment includes sand blasting or etching.

9. The method of claim 1, wherein the wavelength converting layer is provided on the optical layer by spraying coating, spin coating, jet printing, or screen printing.

10. The method of claim 1, wherein the transparent layer is provided between the wavelength converting layer and the multilayered light emitting semiconductor epitaxial structure by spraying coating, spin coating, jet printing, or screen printing.

11. The method of claim 2, wherein the mold is removed prior to cutting the first stack structure.

12. The method of claim 1, further comprising: providing a contact on the multilayered light emitting semiconductor epitaxial structure.

13. A white light emitting diode device, comprising:
a conductive substrate;
a multilayered light emitting semiconductor epitaxial structure formed on the conductive substrate;
a contact provided on the multilayered light emitting semiconductor epitaxial structure;
a transparent layer provided on the multilayered light emitting semiconductor epitaxial structure;
a wavelength converting layer provided on the transparent layer; and
an optical layer provided on the wavelength converting layer.

14. The device of claim 13, wherein the optical layer has a thickness between about 150 μm and about 400 μm.

15. The device of claim 13, wherein the optical layer is made of a polymer.

16. The device of claim 15, wherein the polymer is a silicone resin or an epoxy resin.

17. The device of claim 13, wherein the conductive substrate is a metal, an alloy, or silicon.

18. The device of claim 13, wherein the multilayered light emitting semiconductor epitaxial structure comprises:
a p-type semiconductor layer formed on the conductive substrate;
an active layer formed on the p-type semiconductor layer; and
an n-type semiconductor layer formed on the active layer.

19. The device of claim 13, wherein the multilayered light emitting semiconductor epitaxial structure comprises:
an n-type semiconductor layer formed on the conductive substrate;
an active layer formed on the n-type semiconductor layer; and
a p-type semiconductor layer formed on the active layer.

20. The device of claim 13, wherein the refractive index of the transparent layer is more than or equal to 1.40.

21. The device of claim 13, wherein the transparent layer is made of a polymer.

22. The device of claim 21, wherein the polymer is a silicone resin or an epoxy resin.

23. The device of claim 13, wherein the wavelength converting layer consists of a plurality of wavelength converting sublayers, and each one of the plurality of wavelength converting sublayers comprises a phosphor and an organic resin.

24. The device of claim 13, wherein the wavelength converting layer has a thickness less than about 200 μm.

25. The device of claim 13, wherein the optical layer is in the form of a dome, a convex, a concave, a flat, or a Fresnel lens.

26. The device of claim 13, wherein the optical layer has a roughened surface.
